(19) United States
(12) Patent Application Publication
(10) Pub. No.: US 2016/0064578 A1
(43) Pub. Date: Mar. 3, 2016

(54) PHOTOSENSOR

(71) Applicant: COMMISSARIAT A L'ENERGIE ATOMIQUE ET AUX ENERGIES ALTERNATIVES, Paris (FR)

(72) Inventors: Ujwol PALANCHOKE, Grenoble (FR); Salim BOUTAMI, Grenoble (FR); Serge GIDON, La Murette (FR)

(21) Appl. No.: 14/837,468

(22) Filed: Aug. 27, 2015

(30) Foreign Application Priority Data
Aug. 29, 2014 (FR) 14/58128

(51) Int. Cl. H01L 31/0232; H01L 27/144

(52) U.S. Cl. CPC H01L 31/02327; H01L 27/1446

(57) ABSTRACT

A photosensor, including: first and second photosensitive cells formed next to each other in a semiconductor substrate; first and second dielectric interface layers coating, respectively, the first and second cells; and a resonance grating formed in a third dielectric layer coating the first and second interface layers, wherein the first and second interface layers have different thicknesses, or different refraction indexes, or different thickness and refraction indexes.

This application claims the priority benefit of French Patent application number 14/58128, filed on Aug. 29, 2015, the contents of which is hereby incorporated by reference in its entirety to the maximum extent allowable by law.

### BACKGROUND

The present disclosure relates to the field of photosensors capable of measuring light intensities received in a plurality of determined wavelengths, for example, color image sensors.

### DISCUSSION OF THE RELATED ART

Conventionally, a color image sensor comprises a plurality of identical or similar elementary photosensitive cells (or pixels) formed inside and on top of a semiconductor substrate and arranged in rows and columns. Each photosensitive cell is coated with a color filter, for example, a layer of colored resin, only transmitting to the cell the light of a specific wavelength range. The color filter assembly forms a filtering mosaic arranged above the array of photosensitive cells. As an example, a color image sensor may comprise red, green, and blue filters, arranged in a Bayer pattern above the photosensitive cells.

A disadvantage of conventional color image sensors is their low photoelectric conversion efficiency. Indeed, each color filter transmits to the underlying photosensitive cell the light of a specific wavelength range and reflects or absorbs the light outside of this wavelength range. Thus, considering, as an illustrative example, a photosensor comprising three pixels of same dimensions respectively coated with a red filter, a green filter, and a blue filter, the red filter only receives approximately one third of the red light received across the general sensor collection surface, the green pixel only receives approximately one third of the green light received across the general collection surface of the sensor, and the blue pixel receives only one third of the blue light received across the general collection surface of the sensor.

This particularly raises an issue when sensors comprising pixels of small dimensions are desired to be formed, for example, to increase the sensor resolution and/or decrease the bulk thereof. The small photon collection surface area available for each color then indeed translates as a low sensitivity and a low signal-to-noise ratio of the sensor.

Article “Plasmonic photon sorters for spectral and polarimetric imaging” of Eric Laux et al. (Nature Photonics 2, 161-164 (2008)), describes a spectral sorting device enabling to separate, by wavelength ranges, photons received on a collection surface, and to transmit these photons to different photosensitive cells. In this device, the collection surface is a metal surface structured at the nanometer scale, having the incident light converted into plasmons thereon. The patterns of the metal collection surface are selected to cause a focusing of the plasmons in different areas of the collection surface, according to the wavelength. Once the sorting has been performed, the plasmons are converted back into photons, illuminating the different photosensitive cells. Each photosensitive cell thus receives photons of a specific wavelength range, collected on a collection surface larger than the cell surface.

A disadvantage of this device is its manufacturing complexity, and the relatively high losses resulting from the photon-to-plasmon-to-photon conversion by the metal structure of the device.

It would be desirable to have a photosensor capable of measuring light intensities received in a plurality of different wavelength ranges, this sensor overcoming all or part of the disadvantages of existing sensors.

### SUMMARY

Thus, an embodiment provides a photosensor comprising: first and second photosensitive cells formed next to each other in a semiconductor substrate; first and second dielectric interface layers coating, and being in contact with, respectively, the first and second cells; and a resonance grating formed in a third layer coating, and being in contact with, the first and second interface layers, wherein the first and second interface layers have different thicknesses, or different refraction indexes, or different thickness and refraction indexes.

According to an embodiment, the resonance grating comprises strips or alignments of pads, parallel to the adjacent edge between the first and second cells, delimited by vertical openings formed in the third layer.

According to an embodiment, the adjacent edge between the first and second cells is located under a strip or under a pad alignment of the resonance grating.

According to an embodiment, the assembly comprising the first interface layer and the resonance grating is selected to have a first resonance wavelength defining a first sensitivity wavelength of the sensor, and the assembly comprising the second interface layer and the resonance grating is selected to have a second resonance wavelength different from the first resonance wavelength, defining a second sensitivity wavelength of the sensor.

According to an embodiment, each of the first and second cells has a width in the range from λm/2 to 2λm, where λm designates the average sensitivity wavelength of the sensor.

According to an embodiment, the resonance grating has a pitch in the range from λm/4 to λm, where λm designates the average sensitivity wavelength of the sensor.

According to an embodiment, each of the first, second, and third layers has a thickness in the range from λm/8 to λm, where λm designates the average sensitivity wavelength of the sensor.

According to an embodiment, the sensor further comprises a third photosensitive cell formed in the substrate, and a fourth dielectric interface layer coating the third cell.

According to an embodiment, the assembly comprising the fourth dielectric interface layer and the resonance grating is selected to have a third resonance wavelength, different from the first and second resonance wavelengths, defining a third sensitivity wavelength of the sensor.

According to an embodiment, each dielectric interface layer is made of a material from the group comprising silicon oxide, silicon nitride, MgF₂, HfO₂, Al₂O₃, Ta₂O₅, TiO₂, ZnS, and ZrO₂. According to an embodiment, the third layer is made of a material from the group comprising titanium dioxide, SiN, Ta₂O₅, HfO₂, silicon, and germanium.

The foregoing and other features and advantages will be discussed in detail in the following non-limiting description of specific embodiments in connection with the accompanying drawings.

### BRIEF DESCRIPTION OF THE DRAWINGS

FIGS. 1 and 2 respectively are a simplified perspective view and a simplified cross-section view illustrating an embodiment of a photosensor;

FIG. 3 is a diagram schematically illustrating the response of the sensor of FIGS. 1 and 2 according to the illumination wavelength;

FIG. 4 is a partial simplified top view illustrating an alternative embodiment of a photosensor; and

FIG. 5 is a simplified top view illustrating another alternative embodiment of a photosensor.

### DETAILED DESCRIPTION

For clarity, the same elements have been designated with the same reference numerals in the various drawings and, further, as usual in the representation of integrated circuits, the various drawings are not to scale. Further, in the following description, unless otherwise indicated, terms “approximately”, “substantially”, “around”, “in the order of”, etc. mean “to within 10%”, and terms referring to directions, such as “upper”, “lower”, “topping”, “above”, “lateral”, “horizontal”, “vertical”, etc. apply to devices arranged as illustrated in the corresponding views, it being understood that, in practice, the devices may have different directions.

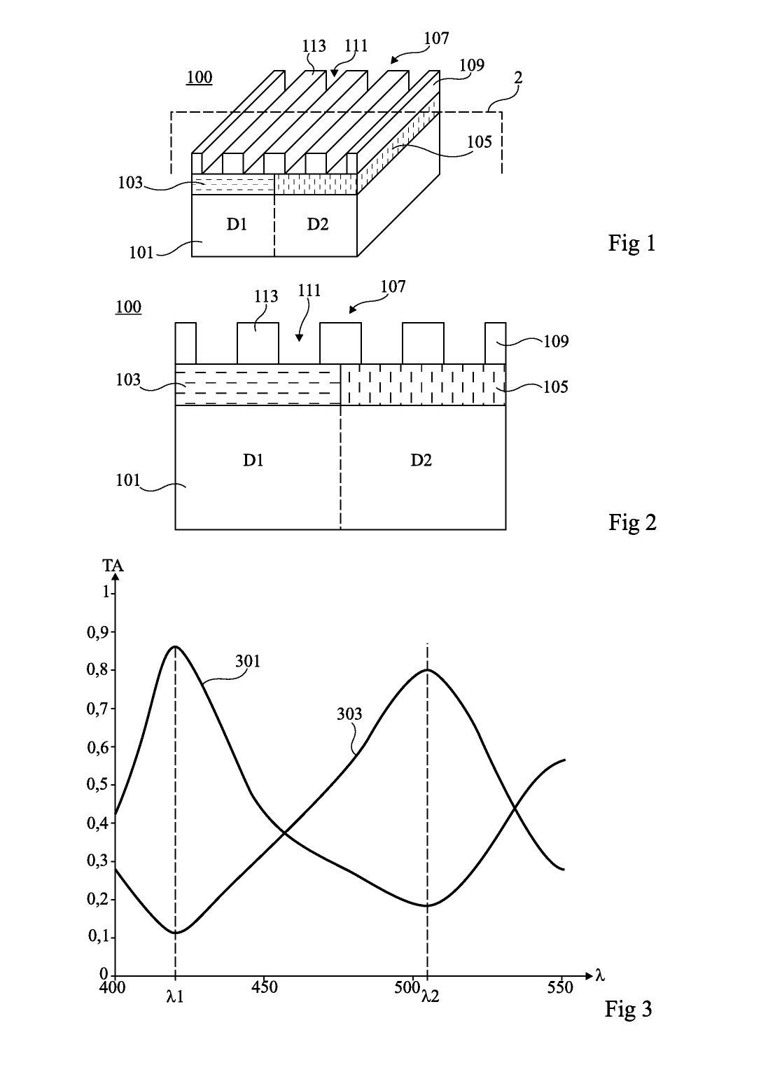

FIG. 1 is a simplified perspective view illustrating an embodiment of a photosensor 100 capable of measuring light intensities received in two different wavelength ranges. FIG. 2 is an enlarged cross-section view of the structure of FIG. 1 in plane 2 of FIG. 1.

In the shown example sensor 100 comprises two elementary photosensitive cells D1 and D2 placed next to each other, formed in a semiconductor substrate 101, for example, a substrate made of silicon, germanium, silicon-germanium, or of any semiconductor material capable of forming photosensitive cells. As an example, each cell comprises a photon detector, for example, a photodiode, and one or a plurality of control MOS transistors. Cells D1 and D2 may be identical or similar. In this example, in top view, cells D1 and D2 have a substantially rectangular shape. The described embodiments are however not limited to this specific case.

Cell D1 is coated, on the side of its surface intended to receive the light (that is, its upper surface in the shown example), with an interface layer 103 made of a dielectric material. In the shown example, layer 103 substantially covers the entire surface of cell D1. Further, cell D2 is coated, on the side of its surface intended to receive the light (that is, its upper surface in the shown example), with an interface layer 105 made of a dielectric material. In the shown example, layer 105 substantially covers the entire surface of cell D2. In this example, layers 103 and 105 substantially have the same thickness, and have different refraction indexes. Layers 103 and 105 are preferably transparent. As an example, layers 103 and 105 are made of materials selected from the group comprising silicon oxide, silicon nitride, MgF₂, HfO₂, Al₂O₃, Ta₂O₅, TiO₂, ZnS, and ZrO₂.

Sensor 100 further comprises a resonance grating 107 formed in a third layer 109 preferably non-metallic, coating interface layers 103 and 105. Layer 109 is preferably transparent. Layer 109 is for example made of a material having a refraction index different from that of layers 103 and 105. As an example, layer 109 is made of a material selected from the group comprising titanium dioxide, SiN, Ta₂O₅, HfO₂, silicon, and germanium. Grating 107 substantially covers the entire upper surface of the assembly formed by cells D1 and D2 and interface layers 103 and 105. Grating 107 comprises vertical openings 111 formed in layer 109, distributed across the entire sensor surface. In the shown example, openings 111 formed in layer 109 are through openings, that is, they extend across the entire thickness of layer 109, and emerge into underlying interface layers 103, 105. The described embodiments are however not limited to this specific case. As a variation, openings 111 defining grating 107 may extend from the upper surface of layer 109, and stop at an intermediate height of layer 109 without thoroughly crossing it. Grating 107 may be coated with a protection material (not shown) having a refraction index smaller than that of layer 109, filling, in particular, openings 111 of the grating, or may be left in free air as shown in FIGS. 1 and 2.

In the example of FIGS. 1 and 2, openings 111 have the shape of strips parallel to the adjacent edge between cells D1 and D2, extending substantially across the entire length of the sensor parallel to the edge adjacent to cells D1 and D2, and delimiting in layer 109 strips 113 parallel to the adjacent edge between cells D1 and D2. As an example, in a direction parallel to the sensor width, that is, perpendicularly to the adjacent edge between cells D1 and D2, slots 111 and strips 113 define a periodic pattern repeated substantially across the entire width of the sensor. The described embodiments are however not limited to this specific case. As a variation, the spacing pitch of slots 111, and/or the ratio of the width of slots 111 to the width of strips 113 may not be exactly the same above interface layer 103 (and thus cell D1) and above interface layer 105 (and thus cell D2).

To illustrate the behavior of a sensor of the type described in relation with FIGS. 1 and 2, the following specific case is considered as a non-limiting example: cells D1 and D2 each have a width (perpendicularly to the adjacent edge between cells) of approximately 500 nm, and are formed in a silicon substrate, interface layer 103 is made of silicon nitride of index n=2, interface layer 105 is made of silicon oxide of index n=1.45, layers 103 and 105 have a thickness of approximately 110 nm, layer 109 having grating 107 formed therein is made of titanium dioxide of index n=2.5 and has a thickness of approximately 110 nm, slots 111 have a width of approximately 125 nm and are periodically distributed across the entire width of the sensor (perpendicularly to the adjacent edge between cells D1 and D2) with a pitch of approximately 250 nm, and grating 107 is coated with an air layer of index n=1.

FIG. 3 is a diagram schematically illustrating the response, according to the wavelength, of each of cells D1 and D2 of sensor 100, for this specific example of sizing and of selection of sensor materials. More particularly, FIG. 3 comprises a curve 301 showing the variation, according to wavelength λ, of normalized rate TA of light absorption by cell D1, and a curve 303 showing the variation according to wavelength λ, of normalized rate TA of light absorption by cell D2. Normalized absorption rate here means the proportion, absorbed by cell D1 (respectively D2), of the light received all over the upper surface of the sensor located opposite cells D1 and D2 (or total collection surface of the sensor). In the shown example, curves 301 and 303 have been plotted for a wavelength range λ from 400 to 550 nm.

In this example, curve 301 comprises an absorption peak centered on a wavelength value λ1 of approximately 430 nm, and reaching a peak absorption value (or maximum) in the order of 0.87 at this wavelength, and further comprises an absorption valley centered on a wavelength value λ2 of approximately 520 nm, and reaching an absorption valley value (or minimum) in the order of 0.2 at this wavelength. Further, in this example, curve 303 comprises an absorption valley centered on wavelength value λ1, and reaching an absorption valley value (or minimum) in the order of 0.13 at this wavelength, and further comprises an absorption peak centered on a wavelength value λ2 of approximately 520 nm, and reaching an absorption peak value (or minimum) in the order of 0.8 at this wavelength. In other words, at wavelength λ1, cell D1 absorbs approximately 87% of the photons received on the total collection surface of the sensor, and cell D2 only absorbs approximately 13% of the received photons and, at wavelength λ2, cell D2 absorbs approximately 80% of the photons received on the total collection surface of the sensor, and cell D1 only absorbs approximately 20% of the received photons. As a comparative example, if, instead of the structure formed by interface layers 103 and 105 and resonance grating 107, cells D1 and D2 were covered with simple filters capable of respectively transmitting wavelength λ1 (cell D1) and wavelength λ2 (cell D2), the normalized absorption rate TA of cell D1 at wavelength λ1 would be in the order of 0.5, and the normalized absorption rate TA of cell D2 at wavelength λ2 would be in the order of 0.5.

Thus, sensor 100 sorts the photons according to the wavelength. In particular, the provision of interface layers 103 and 105 and of resonance grating 107 enables each photosensitive cell to essentially receive photons of a specific wavelength range, collected on a collection surface larger than the upper surface of the cell.

Sensor 100 thus enables to measure light intensities received at wavelengths λ1 and λ2, with a photoelectric conversion efficiency much greater than what could be obtained by using simple colored filters to separate wavelengths λ1 and λ2 (for identical photon collection surface areas).

The inventors have determined that the observed effect of extension of the photon collection surface area, at wavelengths λ1 and λ2, is linked to the fact that interface layer 103 and grating 107 form a structure which is resonant at wavelength λ1, and that interface layer 105 and grating 107 form a structure which is resonant at wavelength λ2.

By adapted analysis and simulation methods, for example, methods of the type generally called RCWA in the art (“Rigorous Coupled-Wave Analysis”), the above-mentioned specific sizing example may be easily adapted to obtain resonances, and thus absorption peaks, at other wavelengths λ1 and λ2 than those of the example of FIG. 3. In particular, one or a plurality of the following parameters may be modified: the width of cells D1 and D2, the thicknesses of layers 103 and 105 and of layer 109, the pitch of grating 107, the width of the slots of grating 107, and the optical index of layers 103, 105, and/or 109.

To obtain a particularly high conversion efficiency, the inventors have observed that it is preferable for the width of the photosensitive cells to be in the range from λm/2 to 2λm, where λm designates the average wavelength of the photons to be filtered or average sensor sensitivity wavelength (that is, λm=(λ1+λ2)/2 in the example with two filtering ranges described in relation with FIGS. 1 and 2). Further, the pitch of resonance grating 107 is preferably in the range from λm/4 to λm. As an example, the pitch of grating 107 is in the order of λm/2. Further, the thicknesses of interface layers 103 and 105 on the one hand, and of layer 109 on the other hand, are preferably in the range from λm/8 to λm. As an example, layers 103, 105, and 109 have a thickness of approximately λm/4.

Further, the inventors have observed that a particularly high efficiency is obtained when one of strips 113 of resonance grating 107 is located above the adjacent edge between cells D1 and D2, and the adjacent edge between cells D1 and D2 approximately coincides (in vertical projection) with the central longitudinal axis of this strip, as shown in FIGS. 1 and 2.

The described embodiments are not limited to the specific example described hereabove where interface layers 103 and 105 have the same thickness and have different refraction indexes. As a variation, layers 103 and 105 may be made of a same material (and thus have identical refraction indexes) and have different thicknesses. Further, layers 103 and 105 may be made of different refraction indexes and have different thicknesses.

Further, a specific example of photosensor only comprising two photosensitive cells D1 and D2 intended to each receive photons of a specific wavelength range λ1 and λ2, respectively) has been described hereabove. The described embodiments are however not limited to this specific example.

As a variation, a two-color image sensor comprising a larger number of photosensitive cells arranged in rows and columns may in particular be provided. As an example, to form such a sensor, the structure of FIGS. 1 and 2 may be repeated widthwise and lengthwise in sensor 100, as many times as necessary to obtain the desired resolution.

Further the example described in relation with FIGS. 1 and 2 may be extended to a sensor enabling to discriminate a number of wavelength bands greater than 2. As an example, a third photosensitive cell may be provided, next to one of cells D1 and D2, this third cell being topped with a third interface layer having a different optical index and/or a different thickness than layers 103 and 105, and by an extension of grating 107.

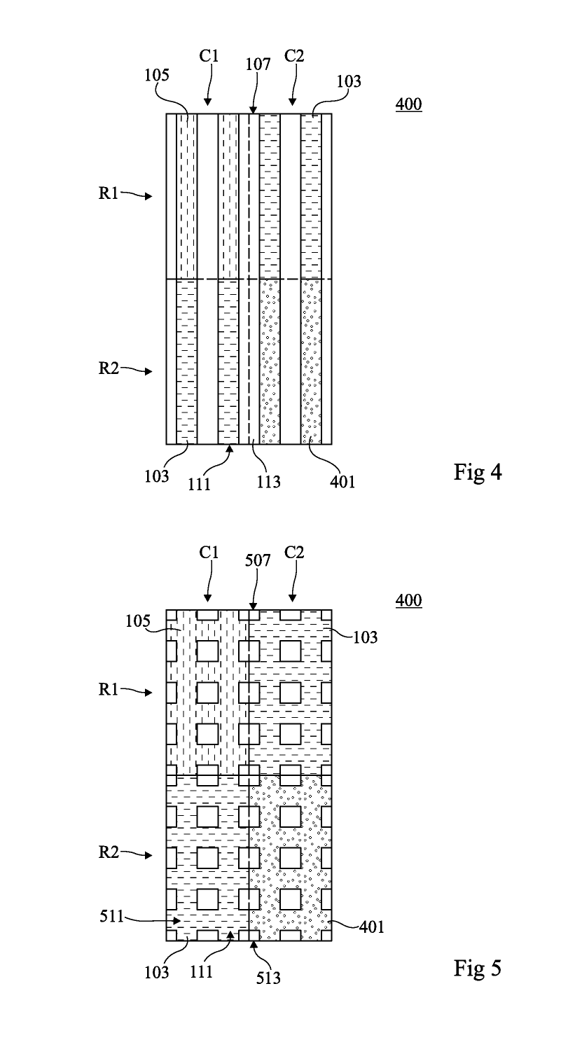

FIG. 4 is a partial simplified top view illustrating an alternative embodiment of a photosensor 400 capable of measuring the light intensity received in three specific wave-length bands. In the shown example, sensor 400 comprises four identical or similar photosensitive cells (not shown in FIG. 4), formed in a semiconductor substrate (not shown in FIG. 1), and arranged in an array, in two rows R1 and R2 and two columns C1 and C2. For practical reasons, although the photosensitive cells are not shown in FIG. 4, references D11, D12, D21, and D22 will respectively be used to designate the cell of row R1 and of column C1, the cell of row R1 and of column C2, the cell of row R2 and of column C1, and the cell of row R2 and of column C2.

Cells D11 and D12 on the one hand, and D21 and D22 on the other hand, are arranged next to each other. Further, in this example, cells D11 and D21 on the one hand, and D12 and D22 on the other hand, are arranged next to each other. Cell D11 is coated with an interface layer 105 identical or similar to that of FIGS. 1 and 2, and cells D12 and D21 are coated with an interface layer 103 identical or similar to that of FIGS. 1 and 2. Cell D22 is covered with a third interface layer 401 made of a dielectric material, layer 401 differing from layers 103 and 105 by its refraction index and/or by its thickness.

A resonance grating 107 identical or similar to that of FIGS. 1 and 2 coats the entire structure formed by cells D11, D12, D21, and D22 and by interface layers 103, 105, and 401. In sensor 400, parallel strips 113 of the resonance grating are arranged parallel to the sensor columns. Preferably, one of strips 113 of the resonance grating is located above the adjacent edge between columns C1 and C2, that is, above the adjacent edge between cells D11 and D12 and above the adjacent edge between cells D21 and D22.

As an example, grating 107 and interface layers 103, 105, and 401 are selected so that cell D11 has an absorption peak in blue, cell D22 has an absorption peak in red, and cells D12 and D21 have an absorption peak in green. Thus, a sensor having a pixel arrangement corresponding to that of a Bayer filter is obtained. A sensor having a greater number of photosensitive cells may be formed by repeating the structure of FIG. 4 in the row direction and in the column direction, as many times as necessary to obtain the desired resolution.

FIG. 5 is a partial simplified top view illustrating an alternative embodiment of photosensor 400 of FIG. 4. Sensor 400 of FIG. 5 differs from the sensor of FIG. 4 by the shape of its resonance grating. In the example of FIG. 5, sensor 400 comprises a resonance grating 507 which differs from grating 107 of FIG. 4 in that each strip 113 of grating 107 is replaced with an alignment 513 of separate pads, regularly distributed along the entire length of the sensor. In other words, in addition to slots 111 parallel to the adjacent edge between columns C1 and C2, grating 507 comprises slots 511 perpendicular to the adjacent edge between columns C1 and C2, regularly spaced apart along the entire sensor length.

It should be noted that this alternative embodiment is also compatible with the example of FIGS. 1 and 2, where each strip 113 of grating 107 may be replaced with a plurality of separate pads aligned along the same longitudinal direction as strip 113.

An advantage of the described embodiments is that they enable to measure light intensities in different wavelength ranges with a high photoelectric conversion efficiency as compared with existing sensors. Such a high efficiency especially results from the fact that, due to the grating resonance at a given color, the photons seem to be collected on a collection surface larger than the surface of the photosensitive cell. Further, the use of dielectric materials to form the interface layers and the resonance grating contributes to the obtaining of a high photoelectric conversion efficiency, since these materials have low losses at the sensor sensitivity wavelengths. Thus, compact sensors having a high sensitivity and a high signal-to-noise ratio with respect to existing sensors can be formed.

Further, the described sensors can be easily formed by conventional integrated circuit manufacturing techniques.

Specific embodiments have been described. Various alterations, modifications, and improvements will readily occur to those skilled in the art.

In particular, the described embodiments are not limited to the above-mentioned examples as to the number of different wavelength bands capable of being detected by the sensor and as to the average values of these wavelengths. More generally, based on the above teachings, it will be within the abilities of those skilled in the art to easily form a photosensor enabling to ensure light intensities in at least two different wavelength ranges selected from the visible or near-visible range, for example, from the wavelength range from 100 to 10,000 nm.

Further, to improve the color discrimination, color filters, for example, colored resin layers, may optionally be added to the above-described structures. As an example, in sensor 400 of FIG. 4, considering the case where cells D11, D12, D21, and D22 have absorption peaks respectively in blue, green, and red (Bayer pattern), it may be provided to arrange a cyan filter above the assembly formed by cells D11 and D12, and a yellow filter above the assembly formed by cells D21 and D22. The cyan filter indeed enables to filter red light and to only transmit to cells D11 and D12 the blue and green light, and the yellow filter enables to filter the blue light and to only transmit to cells D21 and D22 the green and red light.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A photosensor (100; 400) comprising:
first (D1; D12) and second (D2; D11) photosensitive cells formed next to each other in a semiconductor substrate (101);
first (103) and second (105) dielectric interface layers respectively coating, and being in contact with, the first (D1; D12) and second (D2; D11) cells; and
a resonance grating (107; 507) formed in a third layer (109) coating, and being in contact with, the first (103) and second (105) interface layers,
wherein the first (103) and second (105) interface layers have different thicknesses, or different refraction indexes, or different thickness and refraction indexes.

2. The sensor (100; 400) of claim 1, wherein the resonance grating (107; 507) comprises strips (113) or alignments of pads (513), parallel to the adjacent edge between the first (D1; D12) and second (D2; D11) cells, delimited by vertical openings (111; 511) formed in the third layer (109).

3. The sensor (100; 400) of claim 2, wherein the adjacent edge between the first (D1; D12) and second (D2; D11) cells is located under a strip (113) or under a pad alignment (513) of the resonance grating (107; 507).

4. The sensor (100; 400) of claim 1, wherein the assembly comprising the first interface layer (103) and the resonance grating (107; 507) is selected to have a first resonance wavelength (λ1) defining a first sensitivity wavelength of the sensor, and wherein the assembly comprising the second interface layer (105) and the resonance grating (107) is selected to have a second resonance wavelength (λ2) different from the first resonance wavelength (λ1), defining a second sensitivity wavelength of the sensor.

5. The sensor (100; 400) of claim 4, wherein each of the first (D1; D12) and second (D2; D11) cells has a width in the range from λm/2 to 2λm, where λm designates the average sensitivity wavelength of the sensor.

6. The sensor (100; 400) of claim 4, wherein the resonance grating (107; 507) has a pitch in the range from λm/4 to λm, where λm designates the average sensitivity wavelength of the sensor.

7. The sensor (100; 400) of claim 4, wherein each of the first (103), second (105), and third (109) layers has a thickness in the range from λm/8 to λm, where λm designates the average sensitivity wavelength of the sensor.

8. The sensor (400) of claim 4, wherein the assembly comprising the fourth dielectric interface layer (401) and the resonance grating (107; 507) is selected to have a third resonance wavelength, different from the first (λ1) and second (λ2) resonance wavelengths, defining a third sensitivity wavelength of the sensor.

9. The sensor (400) of claim 1, further comprising a third photosensitive cell (D22) formed in the substrate (101), and a fourth interface dielectric layer (401) coating the third cell (D22).

10. The sensor (400) of claim 9, wherein the assembly comprising the fourth dielectric interface layer (401) and the resonance grating (107; 507) is selected to have a third resonance wavelength, different from the first (λ1) and second (λ2) resonance wavelengths, defining a third sensitivity wavelength of the sensor.

11. The sensor (100; 400) of claim 1, wherein each dielectric interface layer (103, 105; 401) is made of a material from the group comprising silicon oxide, silicon nitride, MgF₂, HfO₂, Al₂O₃, Ta₂O₅, TiO₂, ZnS, and ZrO₂.

12. The sensor (100; 400) of claim 1, wherein the third layer (109) is made of a material from the group comprising titanium dioxide, SiN, Ta₂O₅, HfO₂, silicon, and germanium.
